(19) United States
(12) Patent Application Publication
(10) Pub. No.: US 2008/0025525 A1
(43) Pub. Date: Jan. 31, 2008

(54) METHOD FOR CONTROLLING VOLUME OF EARPHONE

(75) Inventor: Wen-Sung Tsai, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: COMPAL ELECTRONICS, INC., Taipei City (TW)

(21) Appl. No.: 11/674,673

(22) Filed: Feb. 14, 2007

(30) Foreign Application Priority Data
Jul. 31, 2006 (TW) 95127926

(51) Int. Cl. H04R 1/10; H03G 3/00

(52) U.S. Cl. 381/74; 381/104; 381/26

(57) ABSTRACT

A method for controlling volume of an earphone is disclosed. The method includes first detecting if a sensor in the earphone is triggered, and then a counter begins to count the time when the sensor is triggered. The counting value of the counter represents an operating time of the earphone. The volume of the earphone is reduced when the operating time reaches a default value. Therefore, the purpose of protecting users' hearing is achieved.

### CROSS-REFERENCE TO RELATED APPLICATION

This application claims the priority benefit of Taiwan application serial no. 95127926, filed Jul. 31, 2006. All disclosure of the Taiwan application is incorporated herein by reference.

### BACKGROUND OF THE INVENTION

1. Field of the Invention

The present invention generally relates to a method for controlling volume, and more particularly to a method for controlling volume of an earphone.

2. Description of Related Art

A single optical disc was merely capable of storing dozens of songs. At present, with the rapid buildup of digital products and advancement of digital audio recording, the optical disc can store hundreds of songs thanks to the audio/video compression technique, such as an MPEG audio layer 3 (MP3). The MP3 format allows a compression of audio content into a small-capacity music file without sacrificing the music quality, which is deeply favored by the consumers. Accordingly, featuring lightness, thinness, and compactness, the music players such as the MP3 players have brought popularity surge in various consumers' electronics.

The portability of the MP3 player achieves the purpose of enjoying music every time everywhere. Listeners can listen to the music by merely connecting the earphone packaged with ear buds to the MP3 player. However, in most cases, listeners are unconsciously encouraged to play the music for a long time or to pump up the volume, developing hearing loss of the listeners. Many studies indicate that more and more young people have experienced some age-related hearing loss because they listen to the music for a long duration without paying attention to the volume control.

The diaphragms in the earphones are positioned closer to users' eardrums in comparison with the diaphragms built in the loudspeakers. Thus, the earphone users experience direct hearing loss in spite that great acoustic entertainment is brought to said users. Currently, external earphones are designed for minimizing hearing damages. Nevertheless, the users still suffer from the auditory disorders such as poor blood circulation, tinnitus, hair cell necrosis of inner ear, and even damage to auditory nerves if using the earphones in a long run. In particular, some users may turn up the volume to block out noisy surroundings, leading to more cases of hearing loss.

If the earphone is not at a high volume, the users may not bear great risk of hearing damages. However, if the users are continuously exposed to excessive sound pressure for a long time, the risk of hearing loss may be dramatically heightened. Thus, said issue has attracted much attention in various countries. For example, the French government enacted regulations in 1996 regarding MP3-related players to limit the volume thereof. Namely, the maximum volume of the music layers must not exceed 100 db. Said limitation merely effects a temporary solution to the issue but not eradicates the same. At this current stage, the conventional music players are still unlikely to protect the users who listen to the music for a long time. Hence, hearing impairment caused by lack of appropriate protective measures still remains.

### SUMMARY OF THE INVENTION

Accordingly, the present invention is directed to a method for controlling volume of an earphone which is capable of appropriately reducing the volume after a duration of an operating time or of sending a break message on the condition that no disturbance to the users is involved. Thereby, the present invention prevents the users from being damaged due to a long-term usage of the earphone.

The present invention provides a method for controlling volume of an earphone based on an operating time of the earphone. The method includes the following steps of first detecting if a sensor in the earphone is triggered. Next, a counter is adopted to count the time when the sensor is triggered, and the counting value of the counter represents an operating time of the earphone. Then, the volume of the earphone is reduced when the operating time reaches a default value.

According to one embodiment of the present invention, after said step of using the counting value of the counter as the operating time of the earphone is performed, the following steps further include determining if the sensor in the earphone is no longer triggered; terminating the calculation of the operating time when the sensor is no longer triggered; and re-detecting if the sensor in the earphone is triggered again.

According to one embodiment of the present invention, a configured mode of volume reduction includes either a proportional volume reduction mode or a dynamic volume reduction mode.

Since the sensor is configured in the earphone for detecting the actual time of operating the earphone according to the present invention, the operating time can be accurately calculated, so as to appropriately reduce the volume after a duration of the operating time. Thereby, the present invention prevents the users' hearing from being damaged due to a long-term usage of the earphone.

In order to the make the aforementioned and other objects, features and advantages of the present invention comprehensible, several embodiments accompanied with figures are described in detail below.

### BRIEF DESCRIPTION OF THE DRAWINGS

FIG. 1 is a block view depicting a volume control of an earphone according to one embodiment of the present invention.

FIG. 2 is a flow chart depicting a method for controlling volume of an earphone according to one embodiment of the present invention.

FIG. 3 is a flow chart depicting a method for controlling volume of an earphone according to another embodiment of the present invention.

FIG. 4 is a flow chart depicting a method for controlling volume of an earphone according to still another embodiment of the present invention.

### DESCRIPTION OF EMBODIMENTS

In order to make the present invention more comprehensible, several embodiments as to each step of controlling volume of an earphone are described below as the examples to prove that the invention can actually be realized.

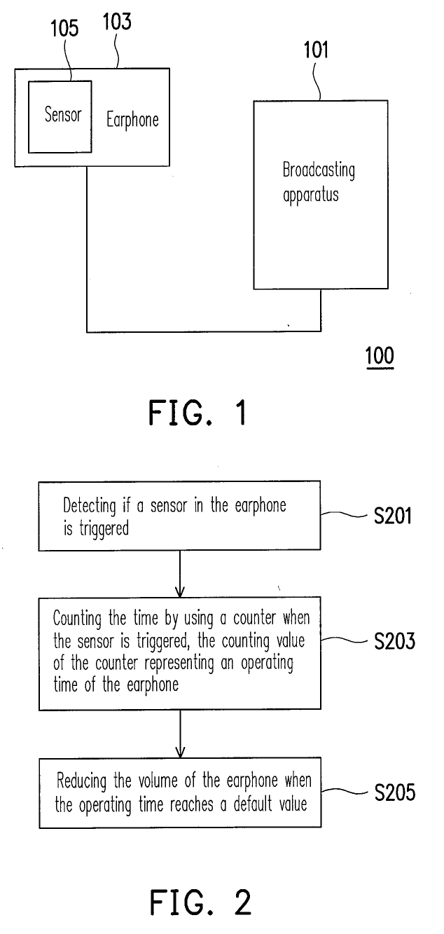

FIG. 1 is a block view depicting a volume control of an earphone according to one embodiment of the present invention. Referring to FIG. 1, a broadcasting system 100 of the present embodiment includes a broadcasting apparatus 101 and an earphone 103. The earphone 103 includes a sensor 105, and connects to the broadcasting apparatus 101. The broadcasting apparatus 101 may be a portable electronic apparatus, such as a mobile phone, a walkman, or an MPEG audio layer 3 (MP3) player. The sensor 105 includes but not limited to a pressure sensor or a thermal sensor, for example.

Again, referring to FIG. 1, as a user starts using the earphone 103 to receive data outputted from the broadcasting apparatus 101, a physical quantity (e.g. temperature, pressure, and so on) is generated by the user. The physical quantity triggers the sensor 105 which then notifies the broadcasting apparatus 101. Thereby, a calculation of an operating time of the earphone 103 is initiated, and volume of the earphone 103 is reduced when the operating time reaches a default value. The default value of time can be adjusted based on actual demands.

FIG. 2 is a flow char t depicting a method for controlling volume of an earphone according to one embodiment of the present invention. Referring to FIG. 2, in step S201, the sensor in the earphone is detected to ascertain if the sensor is triggered. In step S203, if the sensor is indeed triggered, it is represented that the user starts using the earphone, and a counter initiated by the broadcasting apparatus begins to count the time. The counting value of the counter refers to an operating time of the earphone. In step S205, the volume of the earphone is reduced when the operating time reaches a default value which can be adjusted based on the actual demands. Step S205 may further includes sending a warning message to remind users of excessive operating time or unreasonable volume of the earphone. The method of sending the warning message includes but not limited to either displaying a text message on a screen or broadcasting an audio message. Additionally, step S205 further includes reducing the volume of the earphone to the default value. The default value of the volume includes zero decibel (dB) which denotes to turn off the volume output as the operating time reaches a default value. Both the actual default value of the volume and the default duration of time can be adjusted based on the demands.

For example, suppose that the default duration of time is 80 minutes and the default value of the volume is 60 db, when the user starts using the earphone, the sensor in the earphone is triggered and the counter starts to count the time. The counting value of the counter represents the operating time of the earphone. Once the operating time arrives at 80 minutes, the volume of the earphone is reduced to the default value 60 db, so as to prevent hearing damage arisen from a long-term usage of the earphone. Besides, the configured mode of the default volume includes a proportional volume reduction mode and a dynamic volume reduction mode. Said two modes will be illustrated in detail hereinafter, respectively.

According to another embodiment of the present invention, as a user starts using the broadcasting apparatus, a menu is provided by the broadcasting apparatus. The menu includes a proportional volume reduction option. In the present embodiment, the user chooses the proportional volume reduction option and starts using the earphone. The sensor thereof is then triggered and the counter starts counting. As an operating time arrives at a default value of time, the volume of the earphone is reduced to a default value of volume. And the configured mode of the default volume is adjusted based on said proportional volume reduction. Namely, the actually-outputted volume is obtained by multiplying a predetermined ratio by the originally-outputted volume. For example, suppose that the predetermined ratio is 1/2 and the originally-outputted volume is 56 db, the actually-outputted volume is 28 db (56×1/2). That is to say, the volume of the earphone is cut in half as the operating time arrives at the default value, so as to protect the user's hearing. Said examples are taken to facilitate the illustration, and the predetermined ratio can be adjusted based on the actual demands.

According to yet another embodiment of the present invention, as a user starts using the broadcasting apparatus, a menu is provided by the broadcasting apparatus. The menu includes a dynamic volume reduction option. In the present invention, the user chooses the dynamic volume reduction option and starts using the earphone. The sensor thereof is then triggered and the counter starts counting. As an operating time arrives at a default value of time, the volume of the earphone is reduced to a default value of volume. And the configured mode of the default volume is adjusted based on said dynamic volume reduction. Namely, a plurality of actually-outputted volumes and a plurality of volume segments are predetermined. Then, a plurality of corresponding ratios of volume reduction is calculated. Thereafter, the actually-outputted volume is obtained by multiplying an originally-outputted volume by the ratio of volume reduction in the corresponding volume segment.

An example is provided henceforth:

1. Three actually-outputted volumes and three volume segments are taken for examples, and three corresponding ratios of volume reductions are obtained by calculation. The three segments are defined in advance i.e. 0˜50 db, 50˜70 db, and 70˜100 db. In order to distinguish the volume reductions, maximum values 50 db, 70 db and 100 db of the three segments respectively corresponding to the actually-outputted volumes 50 db, 60 db and 70 db are defined. In other words, the maximum outputted volume of the earphone is 70 db.

Specifically, the actually-outputted volume of the earphone is 50 db as the originally-outputted volume of the earphone is 50 db. However, the actually-outputted volume of the earphone is 60 db as the originally-outputted volume of the earphone is 70 db. The actually-outputted volume of the earphone is 70 db as the originally-outputted volume of the earphone is 100 db.

Thereby, the three ratios of the volume reductions (the slopes in the segments) are 1, 6/7, 7/10, respectively. In the present embodiment, the originally-outputted volume is set as 56 db.

2. After one of the volume segments of the originally-outputted volume is determined, it is found that the originally-outputted volume (56 db) falls in the segment of 51˜70 db, and the corresponding ratio of the volume reduction is 6/7.

3. The corresponding ratio (6/7) of the volume reduction in the segment is multiplied by the originally-outputted volume (56 db), and the actually-outputted volume is 48 db (56*6/7).

Thereby, the broadcasting apparatus automatically reduces the volume of the earphone to 48 db after a duration of the operating time, so as to protect the user's hearing. However, the examples are merely taken by the present embodiment to facilitate the illustration. The actually-outputted volume and the numbers and values of the volume segments are not limited in the present invention and can be adjusted based on the demands.

It should be noted that the calculation of the operating time can be further divided into terminating the calculation when the user stops wearing the earphone, or recording the accumulated operating time and adding said time to a subsequent operating time. Thereby, the time point at which the volume is reduced can be determined. Two embodiments are provided hereinafter to illustrate said calculations in detail.

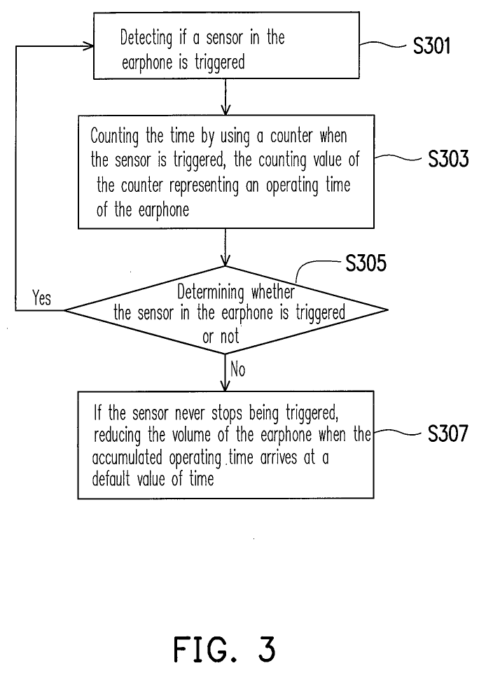

FIG. 3 is a flow chart depicting a method for controlling volume of an earphone according to still another embodiment of the present invention. Referring to FIG. 3, in step S301, a sensor in the earphone is detected to ascertain if the sensor is triggered. In step S303, a counter is adopted to count the time when the sensor is triggered, and the counting value of the counter represents an operating time of the earphone. Next, in step S305, whether the sensor in the earphone is triggered or not is determined. If the sensor is no longer triggered, the calculation of the operating time is terminated. Thereafter, back to step S301, whether the sensor in the earphone is triggered again is re-detected. If the sensor never stops being triggered, the volume of the earphone is reduced when the accumulated operating time arrives at a default value of time, as indicated in step S307. For example, when the user starts using the earphone, the sensor in the earphone is triggered and the counter starts to count the operating time. Given that the user stops using the earphone before the accumulated operating time arrives at the default value, the sensor then stops being triggered and discontinues counting the operating time i.e. resetting the operating time to zero. Next, back to step S301, whether the sensor in the earphone is triggered again is re-detected.

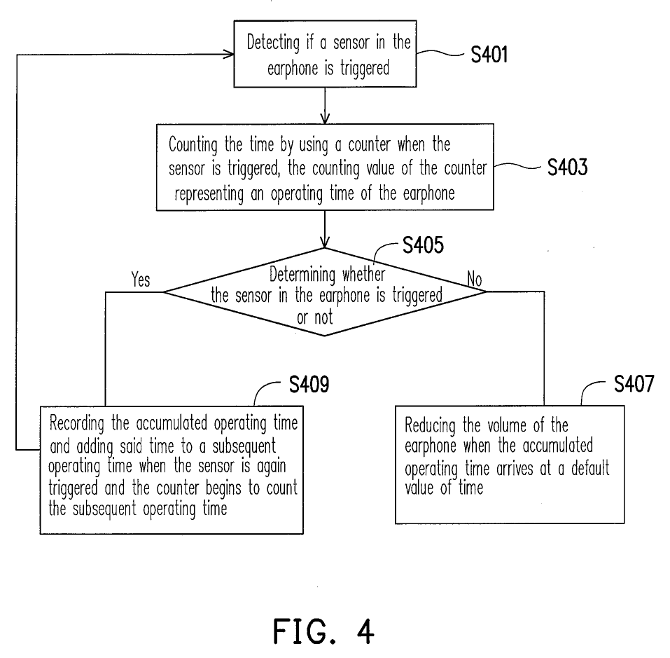

FIG. 4 is a flow chart depicting a method for controlling volume of an earphone according to still another embodiment of the present invention. Referring to FIG. 4, in step S401, a sensor in the earphone is detected to ascertain if the sensor is triggered. In step S403, a counter is adopted to count the time when the sensor is triggered, and the counting value of the counter represents an operating time of the earphone. Next, in step S405, whether the sensor in the earphone is triggered or not is determined. If the sensor never stops being triggered, the volume of the earphone is reduced when the accumulated operating time arrives at a default value of time, as indicated in step S407. On the contrary, if the sensor in the earphone is no longer triggered, the accumulated operating time is recorded so as to add said time to a subsequent operating time when the sensor is again triggered and the counter begins to count the subsequent operating time, as indicated in step S409.

For example, when the user starts using the earphone, the sensor in the earphone is triggered and the counter starts to count the time. Given that the user stops using the earphone before the accumulated operating time arrives at the default value, the sensor then stops being triggered. Next, the accumulated operating time e.g. 5 minutes is recorded so as to add the 5 minutes to a subsequent operating time when the sensor is again triggered and the counter begins to count the subsequent operating time. In other words, the subsequent operating time starts being calculated at 5 minutes. As the accumulated operating time arrives at the default value, the volume of the earphone is reduced.

In view of the foregoing, since the sensor is configured in the earphone for detecting the actual time of operating the earphone according to the present invention, the operating time can be accurately calculated, so as to appropriately reduce the volume after a duration of the operating time. Thereby, the present invention prevents the users' hearing from being damaged due to a long-term usage of the earphone.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for controlling volume of an earphone, comprising the following steps:
(a) detecting if a sensor in the earphone is triggered;
(b) counting the time by using a counter when the sensor is triggered, the counting value of the counter representing an operating time of the earphone; and
(c) reducing the volume of the earphone when the operating time reaches a default value.

2. The method for controlling volume of the earphone according to claim 1, wherein the method further comprises the following steps after step (b):
determining if the sensor in the earphone is no longer triggered;
terminating the calculation of the operating time when the sensor is no longer triggered; and
returning to step (a) and re-detecting if the sensor in the earphone is triggered again.

3. The method for controlling volume of the earphone according to claim 2, wherein the step of terminating the calculation of the operating time further comprises:
recording the accumulated operating time so as to add said operating time to a subsequent operating time when the sensor is again triggered and the counter begins to count the subsequent operating time.

4. The method for controlling volume of the earphone according to claim 1, wherein step (c) further comprises
sending a warning message so as to remind users of the operating time or the volume of the earphone.

5. The method for controlling volume of the earphone according to claim 4, wherein the method of sending the warning message comprises either displaying a text message on a screen or broadcasting an audio message.

6. The method for controlling volume of the earphone according to claim 1, wherein a configured mode for reducing the volume of the earphone comprises either a proportional volume reduction mode or a dynamic volume reduction mode.

7. The method for controlling volume of the earphone according to claim 6, wherein the default volume is obtained by multiplying the volume of the earphone by a certain ratio in the proportional volume reduction mode.

8. The method for controlling volume of the earphone according to claim 6, wherein a range of the volume at which the earphone is capable of broadcasting is divided into a plurality of segments in the dynamic volume reduction mode, and each of the segments corresponds to a certain ratio, the volume in the corresponding segment being multiplied by its corresponding ratio to obtain the default value of the volume.

9. The method for controlling volume of the earphone according to claim 1, wherein step (c) further comprises:
reducing the volume of the earphone to a default volume when the operating time reaches the default value of time.

10. The method for controlling volume of the earphone according to claim 9, wherein the default value of the volume includes zero decibel (dB) which denotes to turn off the volume output.

11. The method for controlling volume of the earphone according to claim 1, wherein the sensor includes either a pressure sensor or a thermal sensor.
